(19) United States
(12) Patent Application Publication
(10) Pub. No.: US 2025/0022744 A1
(43) Pub. Date: Jan. 16, 2025

(54) EXPANSION RETAINING RING

(71) Applicant: Tokyo Seimitsu Co., Ltd., Tokyo (JP)

(72) Inventors: Ryo HIRUMA, Tokyo (JP); Tasuku SHIMIZU, Tokyo (JP)

(73) Assignee: Tokyo Seimitsu Co., Ltd., Tokyo (JP)

(21) Appl. No.: 18/899,620

(22) Filed: Sep. 27, 2024

Related U.S. Application Data
(63) Continuation of application No. PCT/JP2023/010552, filed on Mar. 17, 2023.

(30) Foreign Application Priority Data
Mar. 30, 2022 (JP) 2022-055114

(51) Int. Cl. H01L 21/687; H01L 21/683

(52) U.S. Cl. CPC H01L 21/68721; H01L 21/6836; H01L 2221/68336

(57) ABSTRACT

To provide an expansion retaining ring that may maintain an annular shape of a ring body while ensuring flexibility of a ring-shaped lip. The expansion retaining ring includes a ring body and a ring-shaped lip formed of a material softer than the ring body, the ring-shaped lip being able to be detachably attached to an outer circumferential surface of the ring body and protruding outward from the outer circumferential surface of the ring body.

### CROSS-REFERENCE TO RELATED APPLICATIONS

The present application is a Continuation of PCT International Application No. PCT/JP2023/010552 filed on Mar. 17, 2023 claiming priority under 35 U.S.C § 119 (a) to Japanese Patent Application No. 2022-055114 filed on Mar. 30, 2022.

### BACKGROUND OF THE INVENTION

### Field of the Invention

The present invention relates to an expansion retaining ring, and in particular to an expansion retaining ring for retaining a dicing tape on which a semiconductor wafer is attached in an expanded state.

### Description of the Related Art

Conventionally, in manufacturing semiconductor chips (hereinafter referred to as chips), for example, there is known a workpiece dividing device (dicing device) that divides a semiconductor wafer (hereinafter referred to as a wafer) into individual chips (also referred to as singulation) along scheduled dividing lines which are pre-processed inside the wafer by laser irradiation or the like, (see, for example, Patent Literature 1).

The wafer is attached on a dicing tape, and an outer circumferential part of the dicing tape is fixed to a frame. The workpiece dividing device expands the dicing tape with an expanding ring to divide the wafer into individual chips, and then retains the dicing tape in an expanded state with an expansion retaining ring.

### Citation List

### Patent Literature

Patent Literature 1: Japanese Patent Application Laid-Open No. 2021-176201

### SUMMARY OF THE INVENTION

For example, in an expansion retaining ring in which a ring body and a ring-shaped lip are integrally formed, it may be difficult to maintain an annular shape of the ring body while ensuring flexibility of the ring-shaped lip when a dicing tape is expanded.

In other words, in order to maintain the ring body in the annular shape, it is necessary to apply a resin with high rigidity, for example, a hard resin. However, because this hardens the ring-shaped lip, there is a problem that damaging the dicing tape is damaged when the dicing tape is expanded. As a measure to prevent damage to the dicing tape, it is conceivable to reduce the thickness of the ring-shaped lip to reduce the rigidity of the ring-shaped lip. However, this causes a problem of shortening the service life of the ring-shaped lip. It is also conceivable, as another measure to prevent damage, to apply a soft resin with low rigidity. However, when a dicing tape has high tension, there may be a case where the annular shape of the ring body cannot be maintained, resulting in falling-off of the expansion retaining ring from the frame.

The present invention has been made in view of such problems, and aims to provide an expansion retaining ring that may maintain an annular shape of a ring body while ensuring flexibility of a ring-shaped lip.

In order to achieve the object of the present invention, according to the present invention, an expansion retaining ring for retaining a tape in an expanded state, the tape having an outer circumferential part fixed to a frame, the expansion retaining ring includes: a ring body; and a ring-shaped lip formed of a material softer than the ring body, the ring-shaped lip being able to be detachably attached to an outer circumferential surface of the ring body and protruding outward from the outer circumferential surface of the ring body.

In an embodiment of the present invention, it is preferable that an outer diameter of the ring-shaped lip be larger than an inner diameter of the frame.

In another embodiment of the present invention, it is preferable that the ring body be made of metal, and the ring-shaped lip be made of resin.

In still another embodiment of the present invention, it is preferable that the ring body have an annular recessed part formed along an outer circumferential part of the ring body, and the ring-shaped lip have an annular body part that is inserted and placed in the annular recessed part.

In still another embodiment of the present invention, it is preferable that a dimension of the annular body part in a direction of a central axis of the ring-shaped lip be smaller than a dimension of the annular recessed part in the direction.

In still another embodiment of the present invention, it is preferable that a fluororesin coating layer be provided on an outer surface of the ring body.

In still another embodiment of the present invention, it is preferable that the ring-shaped lip be given a color different from a color of the ring body.

In still another embodiment of the present invention, it is preferable that the ring-shaped lip be given a color different depending on a type of the ring-shaped lip.

In still another embodiment of the present invention, it is preferable that a tapered surface which inclines obliquely with respect to a central axis of the ring body, be formed on an inner circumferential surface of the ring body.

In still another embodiment of the present invention, it is preferable that a dimension of the ring body in a direction of the central axis of the ring body be determined according to a required expansion rate of the tape.

According to the present invention, it is possible to maintain the annular shape of the ring body while ensuring the flexibility of the ring-shaped lip.

### BRIEF DESCRIPTION OF THE DRAWINGS

FIG. 1 is an overall perspective view of an expansion retaining ring according to an embodiment.

FIG. 2 is an assembled perspective view of the expansion retaining ring shown in FIG. 1.

FIG. 3 is a cross-sectional view of the expansion retaining ring shown in FIG. 1.

FIG. 4 is an explanatory diagram of a wafer unit including a dicing tape.

FIG. 5 is an explanatory diagram showing a schematic configuration of a workpiece dividing device.

FIG. 6 is a cross-sectional view showing a state in which a lip body is tilted relative to a ring body.

FIG. 7 is an overall perspective view of a transport device that transports the expansion retaining ring.

FIG. 8 is an enlarged view of a main part of the transport device shown in FIG. 7.

FIG. 9 is an enlarged view of a main part in which the expansion retaining ring is held by the transport device.

FIG. 10 is an enlarged view of a main part showing a positional relationship between the transported expansion retaining ring and an expanding ring.

FIG. 11 is an enlarged view of a main part when the expansion retaining ring is held in an incorrect attitude.

FIG. 12 is an explanatory diagram showing a suction pad that sucks a tapered surface.

FIG. 13 is a cross-sectional view showing another embodiment of an expansion retaining ring.

### DESCRIPTION OF THE EMBODIMENTS

The following describes embodiments of an expansion retaining ring according to the present invention with reference to the accompanying drawings.

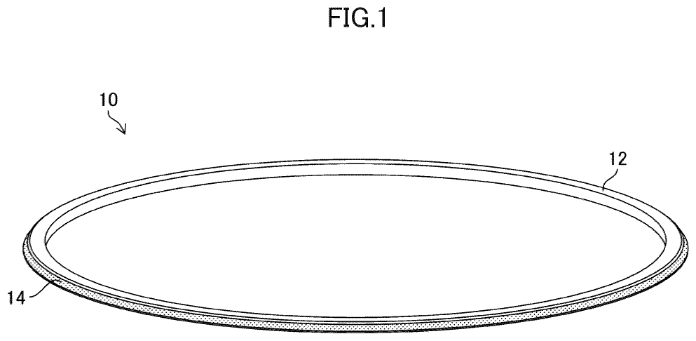

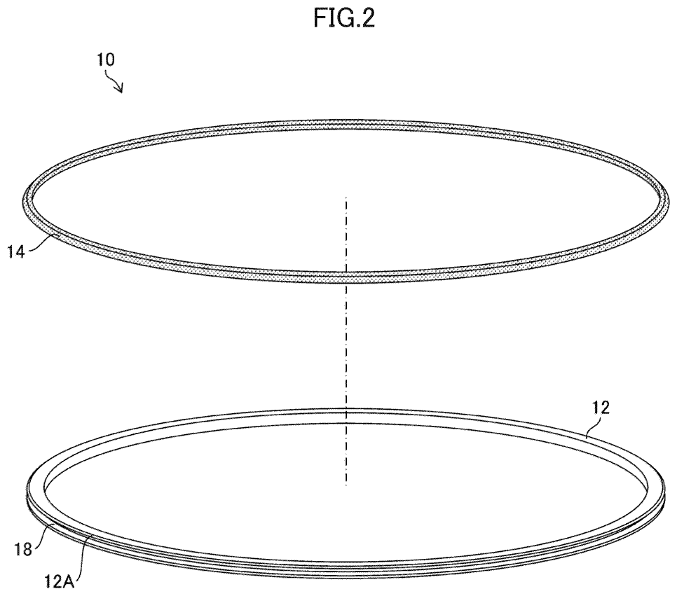

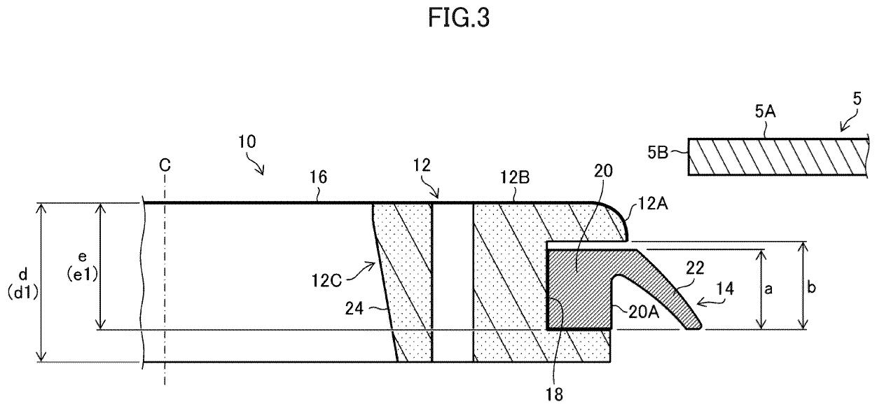

FIG. 1 is an overall perspective view of an expansion retaining ring 10 according to an embodiment, and FIG. 2 is an assembled perspective view of the expansion retaining ring 10 shown in FIG. 1. FIG. 3 is a cross-sectional view of the expansion retaining ring 10 shown in FIG. 1.

As shown in FIGS. 1 to 3, the expansion retaining ring 10 according to the embodiment includes a ring body 12 and a ring-shaped lip 14. The ring body 12 is an example of a ring body of the present invention, and the ring-shaped lip 14 is an example of a ring-shaped lip of the present invention. First, an example of a tape retained in an expanded state by the expansion retaining ring 10 is to be described.

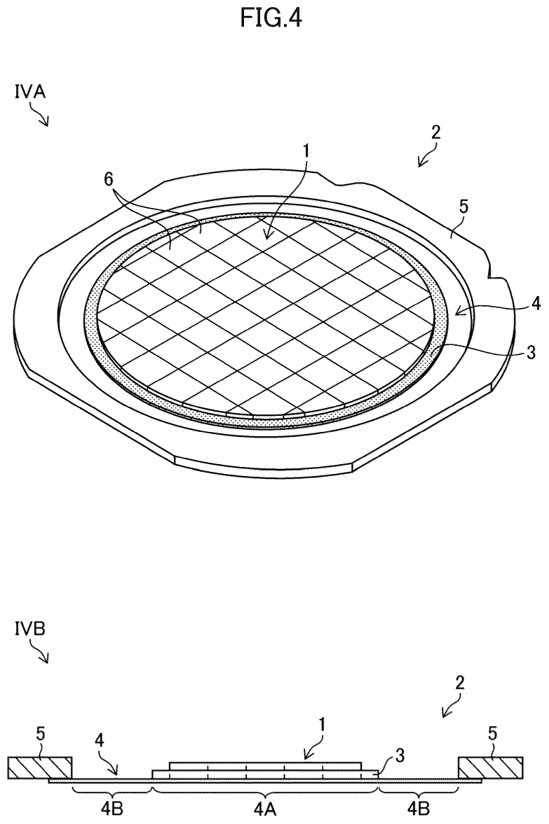

FIG. 4 is an explanatory diagram showing an example of a wafer unit 2. IVA in FIG. 4 is a perspective view of the wafer unit 2, and IVB in FIG. 4 is a cross-sectional view of the wafer unit 2. The wafer unit 2 includes a dicing tape (corresponding to a tape) 4 retained in an expanded state by the expansion retaining ring 10.

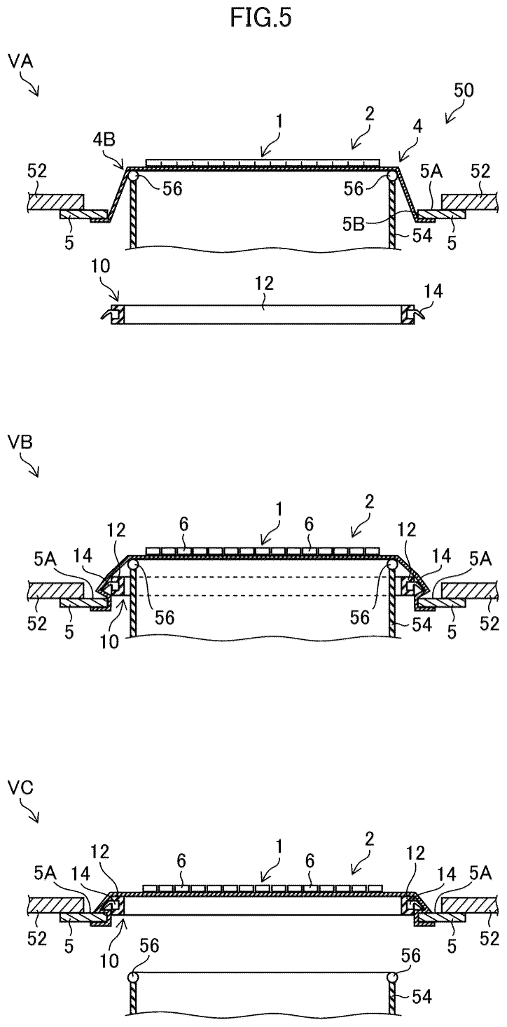

As shown in FIG. 4, the wafer unit 2 has a wafer 1, a film-like adhesive 3, the dicing tape 4, and a frame 5. The wafer 1 is attached on the dicing tape 4, which has a thickness of about 100 μm and has an adhesive layer formed on its surface, via the film-like adhesive 3. An outer circumferential part of the dicing tape 4 is fixed to the rigid ring-shaped frame 5. The dicing tape 4 has: a central part region 4A which is circular in a plan view and the wafer 1 is attached thereon; and an annular part region 4B which is doughnut-shaped in a plan view and lies between the outer edge part of the central part region 4A (the outer edge part of the wafer 1) and the inner edge part of the frame 5. The wafer 1 is carried into a workpiece dividing device 50 (see FIG. 5) in the state of the wafer unit 2, and is divided into individual chips 6 by the workpiece dividing device 50.

FIG. 5 is an explanatory diagram showing a schematic configuration of the workpiece dividing device 50. The chip division movement by the workpiece dividing device 50 is to be briefly described below.

First, as shown in VA in FIG. 5, the frame 5 of the wafer unit 2 is fixed to a frame fixing part 52 of the workpiece dividing device 50. Next, an expanding ring 54 is moved upward to push up the annular part region 4B of the dicing tape 4 from the back surface side of the dicing tape 4 (the back surface is a surface on a side opposite to the surface on which the wafer 1 is attached). The upward movement of the expanding ring 54 expands the dicing tape 4, and divides the wafer 1 into individual chips 6 (see VB in FIG. 5). In addition, rollers 56 are rotatably provided on the upper surface of the expanding ring 54 which pushes up the annular part region 4B, to reduce the frictional force between the annular part region 4B and the expanding ring 54.

Next, as shown in VB in FIG. 5, the expansion retaining ring 10 is moved upward to fit the ring-shaped lip 14 into the surface 5A of the frame 5 via the annular part region 4B (see VC in FIG. 5). The upward movement of the expansion retaining ring 10 retains the dicing tape 4 in the expanded state. Next, as shown in VC of FIG. 5, the expanding ring 54 is moved downward. At this time, the expansion of the dicing tape 4 by the expanding ring 54 is released. However, since the ring-shaped lip 14 of the expansion retaining ring 10 is fitted into the surface 5A of the frame 5, the dicing tape 4 is retained in the expanded state without loosening.

Returning to FIGS. 1 to 3, the expansion retaining ring 10 according to the embodiment is to be further described. As described above, the expansion retaining ring 10 includes the ring body 12 and the ring-shaped lip 14.

The ring-shaped lip 14 is formed of a softer material than the ring body 12. As described later, the ring-shaped lip 14 may be detachably attached to the outer circumferential surface 12A of the ring body 12, and protrudes outward from the outer circumferential surface 12A of the ring body 12. The outer diameter of the ring-shaped lip 14 is configured to be larger than the inner diameter of an opening 5B of the frame 5 (see FIG. 3). With this configuration, while the ring-shaped lip 14 according to this embodiment passes through the opening 5B of the frame 5 shown in FIG. 5, the ring-shaped lip 14 is pressed against the inner edge part of the opening 5B, and elastically deforms so as to reduce its diameter. After the ring-shaped lip 14 has passed through the opening 5B, the ring-shaped lip 14 elastically returns to its original shape and increases its diameter so as to fit into the surface 5A of the frame 5 via the annular part region 4B (see VC in FIG. 5).

The ring body 12 is made of metal, for example. An example of the metal material constituting the ring body 12 may be aluminum, but is not limited to aluminum. Any metal material may be applied as long as the material has high rigidity so as not to easily deform when the dicing tape 4 is expanded (the state VB in FIG. 5) and when the dicing tape 4 is retained in the expanded state (the state VC in FIG. 5). The ring-shaped lip 14 is made of resin, for example. An example of the resin material constituting the ring-shaped lip 14 may be polypropylene, but it is not limited to polypropylene. Any resin material may be applied as long as the resin material has flexibility so as to be easy to elastically deform when the dicing tape 4 is expanded (state VB in FIG. 5).

As shown in FIG. 3, a fluororesin coating layer 16 is provided on the outer surface of the ring body 12. The fluororesin coating layer 16 may reduce the frictional force between the upper surface 12B of the ring body 12 (the surface that pushes up the annular part region 4B) and the annular part region 4B (see FIG. 5). As a result, as shown in VB in FIG. 5, when the expansion retaining ring 10 pushes up the annular part region 4B, the annular part region 4B becomes slippery against the upper surface 12B of the ring body 12. This prevents the dicing tape 4 from being damaged.

As shown in FIG. 3, the ring body 12 has an annular recessed part 18 formed along the outer circumferential surface 12A of the ring body 12. The ring-shaped lip 14 has an annular body part 20 that is inserted and placed into the annular recessed part 18. In other words, according to this embodiment, because of the configuration in which the annular body part 20 is inserted and placed into the annular recessed part 18, the ring-shaped lip 14 is detachably attached to the ring body 12.

The ring-shaped lip 14 has: the annular body part 20; and a lip part 22 that is formed so as to protrude outward from the outer circumferential surface 20A of the annular body part 20 and may be fitted into the surface 5A of the frame 5.

In FIG. 3, when the direction (insertion direction) of inserting the expansion retaining ring 10 into the frame 5 is assumed as the upward direction, the lip part 22 is formed in a shape in which the diameter increases from the part (connection part) connecting the lip part 22 and the annular body part 20, toward a tip part of the lip part 22 on a lower side. The expansion retaining ring 10 having such a lip part 22 may pass through the frame 5 when the expansion retaining ring 10 is moved in the insertion direction (upward), but may not pass through the frame 5 when the expansion retaining ring 10 is moved in the opposite direction (downward) after passing through the opening 5B.

The expansion retaining ring 10 according to the embodiment configured as described above has the following advantages. That is, because the expansion retaining ring 10 has configuration in which the ring-shaped lip 14 is formed of a material softer than the ring body 12 and may be detachably attached to the outer circumferential surface 12A of the ring body 12, it is possible to maintain the annular shape of the ring body 12 while ensuring the flexibility of the ring-shaped lip 14 when the dicing tape 4 is expanded (the state VB in FIG. 5). Note that VB of FIG. 5 shows the dicing tape 4 expanded by the expanding ring 54 and then further expanded by the expansion retaining ring 10. In other words, a state is shown in which the tension of the dicing tape 4 is at its highest.

In addition, since the ring body 12 is made of metal, the annular shape of the ring body 12 is easily maintained. As a result, even when a large tension is applied to the dicing tape 4, it is possible to prevent the expansion retaining ring 10 from falling off the frame 5. In addition, since the ring-shaped lip 14 is made of resin, the ring-shaped lip 14 easily deforms. This makes it possible to prevent the dicing tape 4 from being damaged when the dicing tape 4 is expanded.

As shown in FIG. 3, the expansion retaining ring 10 according to the embodiment is configured such that the dimension a of the annular body part 20 of the ring-shaped lip 14 in the thickness direction of the expansion retaining ring 10 is smaller than the dimension b of the annular recessed part 18. Employing this configuration makes it possible to keep the amount of elastic deformation of the lip part 22 small. Note that the thickness direction of the expansion retaining ring 10 and the direction of the central axis C of the ring-shaped lip 14 are the same direction.

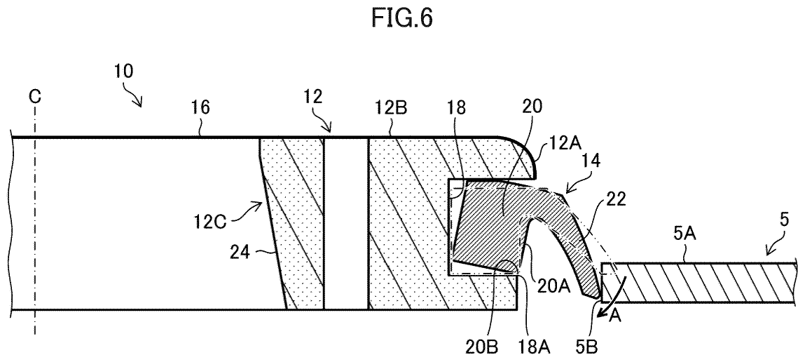

To be more specific, as shown in the cross-sectional view of the expansion retaining ring 10 in FIG. 6, the ring-shaped lip 14 is relatively pressed against the inner edge part of the frame 5 while passing through the opening 5B of the frame 5 (during elastic deformation). In this state, the outer circumference edge part 20B is in contact with an outer circumference end 18A of the annular recessed part 18. As a result, the ring-shaped lip 14 gradually tilts in the direction (downward) indicated by an arrow A with an outer circumference edge part 20B of the annular body part 20 as a fulcrum. The lip part 22 is elastically deformed also in the direction indicated by the arrow A while following the tilting. After having passed through the opening 5B, the lip part 22 then elastically returns to its original shape and fits into the surface 5A of the frame 5.

Here, comparing the configuration according to this embodiment shown in FIGS. 3 and 6, if, for example, the expansion retaining ring has the dimension a of the annular body part 20 that is equal to the dimension b of the annular recessed part 18, the above-described tilting movement of the annular body part 20 (tilting of the annular body part 20 in the direction indicated by the arrow A) is not performed. This causes the amount of elastic deformation of the lip part 22 while passing through the opening 5B to be the amount of summation of the amount of tilting movement of the annular body part 20 and the amount of elastic deformation of the lip part 22 shown in FIG. 6. Therefore, a large load is applied to the lip part 22. Considering this fact, the expansion retaining ring 10 according to the embodiment employs a configuration in which the dimension a of the annular body part 20 is smaller than the dimension b of the annular recessed part 18. This allows the amount of elastic deformation of the lip part 22 to be a smaller amount, resulting in an extended service life of the ring-shaped lip 14. In addition, employing the configuration may reduce the load applied from the lip part 22 to the dicing tape 4, preventing damage to the dicing tape 4.

The expansion retaining ring 10 according to the embodiment employs a configuration in which the ring-shaped lip 14 may be freely attached to and detached from the ring body 12. Therefore, the expansion retaining ring 10 may be repeatedly used in the workpiece dividing device 50 (see FIG. 5). The repeated use may cause the lip part 22 to wear or undergo plastic deformation, causing the lip part 22 to reach its service limit. Even in such a case, the ring-shaped lip 14 may be removed from the ring body 12 and replaced with a new ring-shaped lip 14. Therefore, when the expansion retaining ring 10 according to the embodiment is used, since only the ring-shaped lip 14 needs to be replaced, the cost of replacement may be reduced compared to an expansion retaining ring in which the ring body and the ring-shaped lip are integrated.

As described above, the ring-shaped lip 14 has a service limit on the lip part 22. In that case, for example, when the ring-shaped lip 14 may be managed by manufacturing lot, if one of the ring-shaped lips 14 manufactured in a manufacturing lot reaches its service limit, it may be determined that all of the ring-shaped lips 14 manufactured in that manufacturing lot have reached their service limits.

In the expansion retaining ring 10 according to the embodiment, the ring-shaped lip 14 is given a color different from that of the ring body 12. For example, when the ring body 12 is black, the ring-shaped lip 14 is given a blue color. The ring-shaped lip 14 is given a different color for each manufacturing lot of the ring-shaped lip 14. Therefore, looking at the color given to the ring-shaped lip 14 makes it possible to recognize the manufacturing lot of the ring-shaped lip 14. As a result, when a ring-shaped lip 14 that has exceeded its service limit is found, the use of all the other ring-shaped lips 14 (i.e., expansion retaining rings 10) may be immediately stopped which are manufactured in the same manufacturing lot as the ring-shaped lip 14 having exceeded its service limit. This makes it possible to prevent the expansion retaining ring 10 from falling off the frame 5. In addition, the methods for giving a color to the ring-shaped lip 14 may include a method of adding a pigment to the resin material of the ring-shaped lip 14.

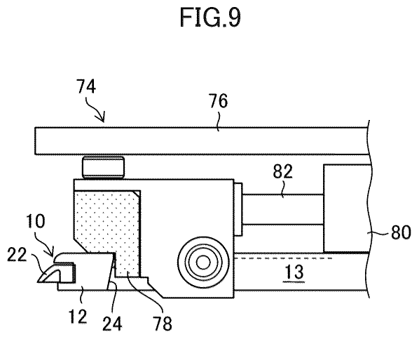

As shown in FIG. 3, the expansion retaining ring 10 according to the embodiment has a tapered surface 24 formed on the inner circumferential surface 12C of the ring body 12. The tapered surface 24 inclines obliquely with respect to the central axis C of the ring body 12. In FIG. 3, when the direction of inserting the expansion retaining ring 10 into the frame 5 is defined as the upward direction, the tapered surface 24 inclines in a direction in which the diameter of an opening part 13 of the ring body 12 (see FIG. 9) gradually increases from the upper part toward the lower part. This tapered surface 24 is effectively used when the expansion retaining ring 10 is transported, as is to be described later. An example of a transport device for transporting the expansion retaining ring 10 is described below.

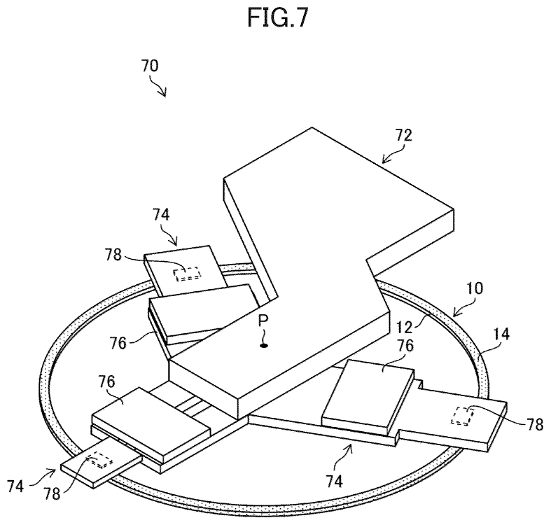

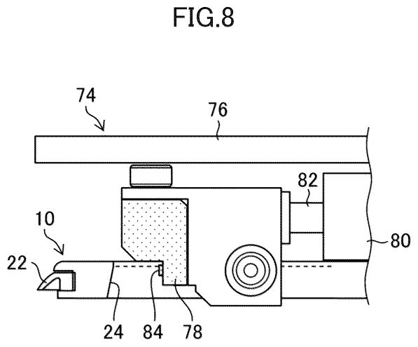

FIG. 7 is an overall perspective view of a transport device 70 for transporting the expansion retaining ring 10, and FIG. 8 is an enlarged view of a main part of the transport device 70 shown in FIG. 7. As shown in FIGS. 7 and 8, the transport device 70 includes a transport arm 72 and three chucking mechanisms 74.

As shown in FIG. 7, each chucking mechanism 74 has a bracket 76 connected to the transport arm 72. Each bracket 76 extends radially from a center that is the holding fulcrum P of the transport arm 72. As shown in FIG. 8, a cylinder 80 is attached to the head end side of each bracket 76, and a clamp claw 78 is attached to the head end of a piston 82 of each cylinder 80.

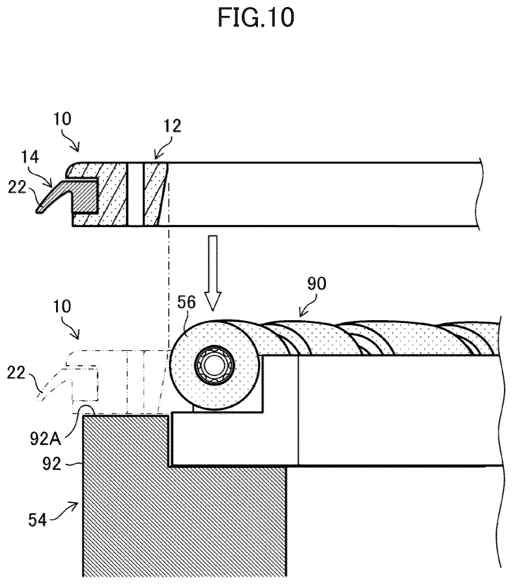

The clamp claws 78 are placed at equal intervals (120 degree intervals) on a concentric circle centered at the holding fulcrum P shown in FIG. 7. The clamp claws 78 move to reciprocate in the radial direction of the concentric circle in accordance with the extension and contraction movements of the piston 82 shown in FIG. 8. The extension movement of the piston 82 moves each clamp claw 78 radially outward from the position (retraction position) shown in FIG. 8. When each clamp claw 78 reaches the position (holding position) shown in FIG. 9, each clamp claw 78 is pressed to come into contact with the tapered surface 24 of the expansion retaining ring 10. This movement causes the expansion retaining ring 10 to be held (chucked) by each chucking mechanism 74. Then, the expansion retaining ring 10 is transported by the transport movement of the transport arm 72 to, for example, a position above the expanding ring 54 shown in FIG. 10.

FIG. 10 is an enlarged view of a main part showing the positional relationship between the transported expansion retaining ring 10 and the expanding ring 54. As shown in FIG. 10, when the expansion retaining ring 10 is transported to the position above the expanding ring 54, the clamp claws 78 in the holding position shown in FIG. 9 are moved radially inward by the contraction movement of the piston 82 to the retraction position shown in FIG. 8. This movement releases the holding (chucking) of the expansion retaining ring 10 by the chucking mechanisms 74, and the expansion retaining ring 10 drops toward the expanding ring 54.

As shown in FIG. 10, the expanding ring 54 includes: a roller ring 90 having rollers 56; and a roller ring receiving part 92 having an outer diameter larger than the outer diameter of the roller ring 90. The dropped expansion retaining ring 10 is seated on the upper surface 92A of the roller ring receiving part 92. The roller ring receiving part 92 is provided with seating sensors (e.g., at three positions) not shown. The seating sensors detect whether or not the expansion retaining ring 10 is correctly seated on the upper surface 92A. In the case of the workpiece dividing device including the expanding ring 54 having the roller ring receiving part 92, the expansion retaining ring 10 is also moved upward together with upward movement of the expanding ring 54, and expands the dicing tape 4 together with the expanding ring 54.

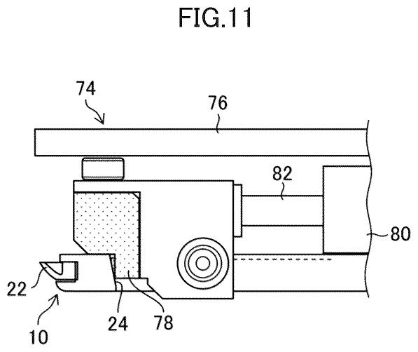

Here, in the transport device 70 shown in FIGS. 7 to 9, each chucking mechanism 74 detects whether the expansion retaining ring 10 is held in the correct attitude. The correct attitude is an attitude for correctly setting the expansion retaining ring 10 on the expanding ring 54 shown in FIG. 10. The correct attitude here is an attitude shown in FIGS. 8 and 9 (the attitude in which the lip part 22 hangs downward). In contrast to this correct attitude, in an incorrect attitude where the expansion retaining ring 10 is held upside down, shown in FIG. 11 (the attitude in which the lip part 22 extends upward), the expansion retaining ring 10 cannot be correctly set on the expanding ring 54. Therefore, in a case where the expansion retaining ring 10 is held in the incorrect attitude, it is necessary to detect the incorrect attitude and stop the transportation of the expansion retaining ring 10. Therefore, the transport device 70 detects the incorrect attitude by using the tapered surface 24 of the expansion retaining ring 10. The following briefly describes an example of a detection device for detecting the incorrect attitude.

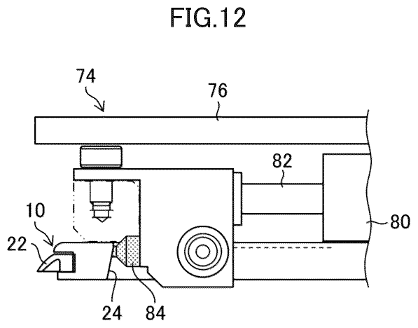

The detection device according to the embodiment employs a configuration for detecting the incorrect attitude using a suction pressure sensor (not shown) and a cylinder sensor (not shown). To be more specific, as shown in FIG. 12, each chucking mechanism 74 has a suction pad 84 that integrally moves together with the clamp claw 78 (see FIG. 8) by the piston 82. The suction pad 84 is provided at a position where the suction pad 84 may suck the tapered surface 24 when the clamp claw 78 is pressed to come into contact with the tapered surface 24. When the suction pad 84 sucks the tapered surface 24, a negative pressure is generated between the suction pad 84 and the tapered surface 24, and the negative pressure is detected by the suction pressure sensor.

Each chucking mechanism 74 also has the cylinder sensor that detects the amount of extension of the piston 82. The cylinder sensor according to this embodiment sets the amount of extension of the piston 82 when the clamp claw 78 is pressed to come into contact with the tapered surface 24 in the correct attitude (see FIG. 9), to within the sensor range. Further, the cylinder sensor sets the amount of extension of the piston 82 when the clamp claw 78 is pressed to come into contact with the tapered surface 24 in the incorrect attitude where the expansion retaining ring 10 is held upside-down (see FIG. 11), to outside the sensor range.

To be more specific, as shown in FIG. 9, when the expansion retaining ring 10 is held in the correct attitude, the tapered surface 24 of the expansion retaining ring 10 inclines in a direction in which the diameter of the opening part 13 of the ring body 12 increases from the upper part toward the lower part. In the correct attitude shown in FIG. 9, each clamp claw 78 is pressed to come into contact with the upper part of the tapered surface 24 (the small diameter part of the opening part 13). Contrarily, as shown in FIG. 11, when the expansion retaining ring 10 is held upside-down to be in the incorrect attitude, the clamp claw 78 is pressed to come into contact with the large diameter part located below the position of the small diameter part in FIG. 9. In other words, the extension amount of the piston 82 is larger when the expansion retaining ring 10 is held upside-down to be in the incorrect attitude than when it is held in the correct attitude. As described above, the tapered surface 24 is used to differentiate the amount of extension of the piston 82 between in the correct attitude and in the incorrect attitude. Accordingly, it is possible to set the amount of extension of the piston 82 when the expansion retaining ring 10 is held in the correct attitude (see FIG. 9) to within the sensor range, and to set the amount of extension of the piston 82 when the expansion retaining ring 10 is held upside-down to be in the incorrect attitude (see FIG. 11) to outside the sensor range.

According to the detection device according to this embodiment, when each clamp claw 78 is pressed to come into contact with the tapered surface 24 in the correct attitude (see FIG. 9), the suction pressure sensor detects a negative pressure, and the cylinder sensor detects the amount of extension of the piston 82. In other words, when both sensors are on, it is determined that the expansion retaining ring 10 is held in the correct attitude, and the expansion retaining ring 10 is permitted to be transported.

Contrarily, when each clamp claw 78 is pressed to come into contact with the tapered surface 24 in a state where the expansion retaining ring 10 is in the upside-down incorrect attitude (see FIG. 11), the extension amount of the piston 82 is larger than when the clamp claw 78 is pressed to come into contact with the tapered surface 24 in a state where the expansion retaining ring 10 is in the correct attitude (see FIG. 9). In this case, the suction pressure sensor detects a negative pressure, but the cylinder sensor does not react because it is outside the sensor range. In other words, since both sensors do not turn on, it is determined that the expansion retaining ring 10 is held in the incorrect attitude, and the expansion retaining ring 10 is not permitted to be transported. In this case, it is preferable to issue a warning by displaying an error pop-up on the operation screen of the workpiece dividing device 50, for example.

Returning to FIG. 3, the expansion retaining ring 10 is to be further described. The expansion retaining ring 10 has a dimension d (d1) of the ring body 12 in the thickness direction of the expansion retaining ring 10 (the direction of the central axis C of the ring-shaped lip 14) determined according to the required expansion rate of the dicing tape 4.

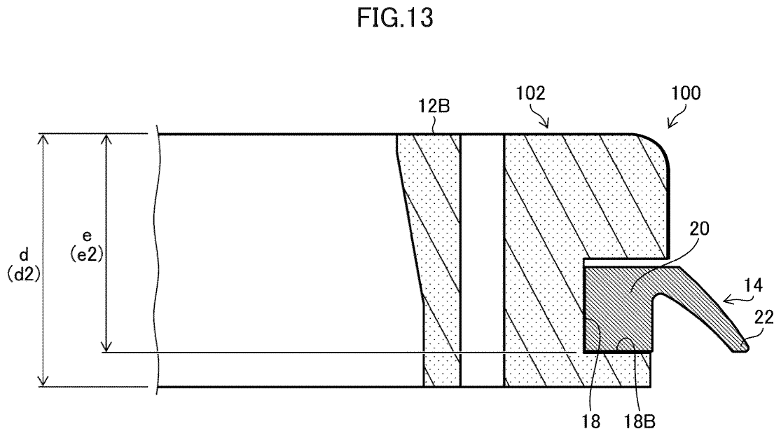

Here, the description is to be made with reference to an expansion retaining ring 100 shown in FIG. 13 of another embodiment. In describing the expansion retaining ring 100, the same or similar members as those in the expansion retaining ring 10 shown in FIG. 3 are to be described with the same reference numerals and characters.

In the case of the dicing tape 4 that requires a high expansion rate, a ring body 102 is used in which the dimension d is changed from d1 (see FIGS. 3) to d2 (d1<d2), as in the expansion retaining ring 100 shown in FIG. 13. To be more specific, the ring body 102 is used in which the dimension e is changed from e1 (see FIG. 3) to e2 (e1<e2). Here, the dimension e is a dimension between the mounting surface 18B, of the inner surfaces of the annular recessed part 18, on which the ring-shaped lip 14 is placed; and the upper surface 12B. The ring-shaped lip 14 is attached to the annular recessed part 18 of the ring body 102 without any change.

Because the expansion retaining ring 100 shown in FIG. 13 includes the ring body 102 with the dimensions (d2, e2), the expansion retaining ring 100 is suitable for the dicing tape 4 that requires a high expansion rate. In the case of the dicing tape 4 that requires a low expansion rate, the above dimensions (d, e) just need to be reduced according to the required expansion rate.

As described above, the expansion retaining rings 10 and 100 of the above-described embodiments employ the configuration such that the ring-shaped lip 14 may be detachably attached to the ring bodies 12 and 102. Therefore, the ring body 12 is selected and used corresponding to the required expansion rate, but the ring-shaped lip 14 may be used in common. In other words, according to the expansion retaining rings 10 and 100 according to the embodiments, only molds need to be prepared for manufacturing the ring bodies 12 and 102 according to the required expansion rate, and only one type of mold may serve for manufacturing the ring-shaped lip 14.

In the above-described embodiments, description has been made with the expansion retaining rings 10 and 100 for retaining the dicing tape 4 in an expanded state. However, it is also possible to use the expansion retaining rings 10 and 100 to expand the dicing tape 4 and divide the wafer 1 into individual chips. In other words, the expansion retaining rings 10 and 100 may also have the function of the expanding ring 54 added thereto. In this case, the expansion retaining rings 10 and 100 are moved up and down relative to the wafer unit 2. Thereby, the ring bodies 12 and 102 of the expansion retaining rings 10 and 100 push up the annular part region 4B of the dicing tape 4. This allows the expansion retaining rings 10 and 100 to divide the wafer 1 into the individual chips 6. The expansion retaining rings 10 and 100 then retain the dicing tape 4 in an expanded state.

Although an example of the expansion retaining ring according to the present invention has been described above, the technique of the present invention is not limited to the embodiments, and some improvements or modifications may be made without departing from the gist of the present invention.

### Reference Signs List

1. . . wafer, 2. wafer unit, 3. film-like adhesive, 4 . . . dicing tape, 5 . . . frame, 10 . . . expansion retaining ring, 12 . . . ring body, 14 . . . ring-shaped lip, 16 . . . fluororesin coating layer, 18 . . . annular recessed part, 20 . . . annular body part, 22 . . . lip part, 24 . . . tapered surface, 50 . . . workpiece dividing device, 52 . . . frame fixing part, 54 . . . expanding ring, 56 . . . roller, 70 . . . transport device, 72 . . . transport arm, 74 . . . chucking mechanism, 76 . . . bracket, 78 . . . clamp claw, 80 . . . cylinder, 82 . . . piston, 84 . . . suction pad, 90 . . . roller ring, 92 . . . roller ring receiving part, 100 . . . expansion retaining ring, 102 . . . ring body

What is claimed is:

1. An expansion retaining ring for retaining a tape in an expanded state, the tape having an outer circumferential part fixed to a frame, the expansion retaining ring comprising:
a ring body; and
a ring-shaped lip formed of a material softer than the ring body, the ring-shaped lip being able to be detachably attached to an outer circumferential surface of the ring body and protruding outward from the outer circumferential surface of the ring body.

2. The expansion retaining ring according to claim 1, wherein an outer diameter of the ring-shaped lip is larger than an inner diameter of the frame.

3. The expansion retaining ring according to claim 1, wherein
the ring body is made of metal, and
the ring-shaped lip is made of resin.

4. The expansion retaining ring according to claim 1, wherein
the ring body has an annular recessed part formed along an outer circumferential part of the ring body, and
the ring-shaped lip has an annular body part that is inserted and placed in the annular recessed part.

5. The expansion retaining ring according to claim 4, wherein a dimension of the annular body part in a direction of a central axis of the ring-shaped lip is smaller than a dimension of the annular recessed part in the direction.

6. The expansion retaining ring according to claim 1, wherein a fluororesin coating layer is provided on an outer surface of the ring body.

7. The expansion retaining ring according to claim 1, wherein the ring-shaped lip is given a color different from a color of the ring body.

8. The expansion retaining ring according to claim 7, wherein the ring-shaped lip is given a color different depending on a type of the ring-shaped lip.

9. The expansion retaining ring according to claim 1, wherein a tapered surface which inclines obliquely with respect to a central axis of the ring body, is formed on an inner circumferential surface of the ring body.

10. The expansion retaining ring according to claim 1, wherein a dimension of the ring body in a direction of the central axis of the ring body is determined according to a required expansion rate of the tape.
